(19) United States
(12) Patent Application Publication
(10) Pub. No.: US 2013/0082287 A1
(43) Pub. Date: Apr. 4, 2013

(54) Thin Film Transistor and Manufacturing Method thereof, Array Substrate, and Liquid Crystal Display Device

(71) Applicant: Hsiaohsien Chen, Shenzhen (CN)

(72) Inventor: Hsiaohsien Chen, Shenzhen (CN)

(21) Appl. No.: 13/318,608

(22) PCT Filed: Oct. 9, 2011
(86) PCT No.: PCT/CN2011/080591

§ 371 Date: Nov. 2, 2011

(30) Foreign Application Priority Data
Sep. 29, 2011 (CN) 201110293403.6

(51) Int. Cl. H01L 33/62; H01L 21/283; H01L 29/772

(52) U.S. Cl. 257/88; 257/288; 438/585; 257/E29.242; 257/E21.19; 257/E33.062

(57) ABSTRACT

The present invention discloses a thin film transistor (TFT), a manufacturing method thereof, an array substrate, and a liquid crystal display (LCD) device. The TFT comprises a gate electrode and a source electrode. The gate electrode comprises a first metal layer block and a second metal layer block positioned on the first metal layer block. The thermal expansion coefficient of the second metal layer block is less than that of the first metal layer block. The top surface of the first metal layer block is in contact with the bottom surface of the second metal layer block, and the width of the top surface of the first metal layer block accords with that of the bottom surface of the second metal layer block. The present invention can prevent hillocks from being produced, and can effectively avoid the phenomenon of electricity leakage.

### TECHNICAL FIELD

The present invention relates to the field of liquid crystal displays (LCDs), and more particularly to a thin film transistor (TFT), a manufacturing method thereof, an array substrate, and an LCD device.

### BACKGROUND

As one of the crucial components of an LCD device, an array substrate comprises multiple TFTs, and each TFT comprises a source electrode and a gate electrode. When a gate electrode is formed, Al, Cu, Au and the like are usually used to make a layer of metal layer block. These materials have a high expansion coefficient, and when heated in the process of manufacturing, the thermal expansion of the upper layer structure and the lower layer structure of the materials does not match, and thus small bumps, called hillocks, are produced. To solve the problem, the U.S. Pat. No. 5,905,274 discloses a method for preventing hillocks from being produced. The principle is that, another metal layer, made of materials, such as Mo, Ta, Co and the like that are not easy to expand, is arranged on the metal layer block to prevent hillocks from being produced. Thus, a double layer of gate electrode is formed. The first and the second metal layer blocks are arranged on the substrate. The first metal layer block is mainly used for conducting the electric property, and the second metal layer block is mainly used for preventing hillocks from being produced. But tests have shown that, in the manufacturing process, the double layer of metal structure causes electricity leakage.

### SUMMARY

The aim of the present invention is to provide a TFT, a manufacturing method thereof, an array substrate, and an LCD device, to prevent hillocks from being produced and prevent electricity leakage.

The purpose of the present invention is achieved by the following technical schemes.

A thin film transistor comprises a gate electrode and a source electrode, wherein the gate electrode comprises a first metal layer block and a second metal layer block positioned on the first metal layer block; the thermal expansion coefficient of the second metal layer block is less than that of the first metal layer block; the top surface of the first metal layer block is in contact with the bottom surface of the second metal layer block, and the width of the top surface of the first metal layer block accords with that of the bottom surface of the second metal layer block.

Preferably, the cross section of the first metal layer block and the second metal layer block is a trapezoid. This is a specific structure of the gate electrode and can be formed by an etching process.

Preferably, each included angle formed by the side surfaces and the bottoms of the first metal layer block and the second metal layer block is more than 30° and less than 60°.

Preferably, the included angle is 45°.

Preferably, the included angles formed by the side surfaces on the same side and the bottoms of the first metal layer block and the second metal layer block are the same.

A manufacturing method of a TFT comprises the following step:

A: Forming a first metal layer block, and forming a second metal layer block positioned on the first metal layer block a the substrate by exposure, development, and etching process, wherein the width of the top surface of the first metal layer block accords with that of the bottom surface of the second metal layer block.

Preferably, the step A comprises the following steps:

A1: Plating a first metal layer on the substrate, applying a first photoresist layer on the first metal layer, and forming the first metal layer block of a TFT gate electrode by exposure, development, and etching process; and

A2: Removing the first photoresist layer, plating a second metal layer on the first metal layer block, applying a second photoresist layer in the position of the second metal layer corresponding to the first metal layer block, and forming the second metal layer block of the TFT gate electrode by exposure, development, and etching process.

In the method, the first photoresist layer and the second photoresist layer are respectively used when etching the first metal layer and the second metal layer. Thus, the etching processes of the two metal layers are not mutually affected, and accurate control is performed in the process of respectively forming the first metal layer block and the second metal layer block, thereby improving the machining accuracy.

Preferably, the step A comprises the following steps:

A1: Sequentially plating the first metal layer and the second metal layer on the substrate; and

A2: Applying the photoresist layer, and forming the first metal layer block of the TFT gate electrode by exposure, development, and etching process; and then etching the second metal layer by using the same photoresist layer to form the second metal layer block. The method has the advantages that the first metal layer block and the second metal layer block are formed simultaneously by using the photoresist layer only once; the manufacturing procedure is simplified, and the manufacturing cost is reduced.

Preferably, in the step A, the appointed degree of the included angle formed by the side and bottom of the first metal layer block and the second metal layer block is achieved by controlling the etching time during etching process. This is a specific embodiment for controlling the degree of the included angle.

An array substrate comprises the aforementioned TFT.

An LCD device comprises the aforementioned array substrate.

It has shown by many investigation tests that, the reason of electricity leakage of the TFT gate electrode of a double layer metal structure in the prior art is: the two layers of metal produce two trapezoidal structures because the two layers of materials have different speed of etching, so that the width of the baseline of the first metal layer block is different from that of the topline of the second metal layer block which is in contact with the first metal layer block; namely the width of the topline of the first metal layer block is W1, and the width of the baseline of the second metal layer block is W2, so that partial topline of the first metal layer block is exposed to cause electricity leakage. In the present invention, the width of the top surface of the first metal layer block of the TFT gate electrode accords with that of the bottom surface of the second metal layer block. Thus, the surface of the first metal layer block which is in contact with the second metal layer completely coheres with the second metal layer, and the contact surface when being charged does not have an exposed area so that the phenomenon of electricity leakage can be avoided. The present invention has the advantages of simple structure, easy manufacture, reduction of excellent rate loss caused by hillocks, and no production of electricity leakage caused by poor step coverage. Therefore, the hillocks can be prevented from being produced, and the phenomenon of electricity leakage can be effectively avoided.

### BRIEF DESCRIPTION OF FIGURES

FIG. 1 is a schematic diagram of an existing TFT gate electrode;

FIG. 2 is a schematic diagram of a TFT gate electrode of the present invention;

FIG. 3 is a diagram of forming a first metal block of the first embodiment of the present invention;

FIG. 4 is a diagram of forming a second metal block of the first embodiment of the present invention;

FIG. 5 is a diagram of forming a first metal block of the second embodiment of the present invention;

FIG. 6 is a diagram of forming a second metal block of the second embodiment of the present invention;

FIG. 7 is a diagram of forming a TFT gate electrode manufactured by the method of the present invention;

FIG. 8 is a schematic diagram of an insulating layer and an ohmic contact layer which are manufactured by the method of the present invention;

FIG. 9 is a schematic diagram of a source electrode manufactured by the method of the present invention; and

FIG. 10 is a schematic diagram of a TFT manufactured by the method of the present invention.

Wherein: 1. substrate; 2. a first metal layer block; 3. a second metal layer block; 4. photoresist layer; 41. a first photoresist layer; 42. a second photoresist layer; 6. insulating layer; 7. semiconductor layer; 8. ohmic contact layer; 9. source electrode; 10. a second insulating layer; 11. pixel electrode.

### DETAILED DESCRIPTION

The present invention will further be described in detail in accordance with the figures and the preferred embodiments.

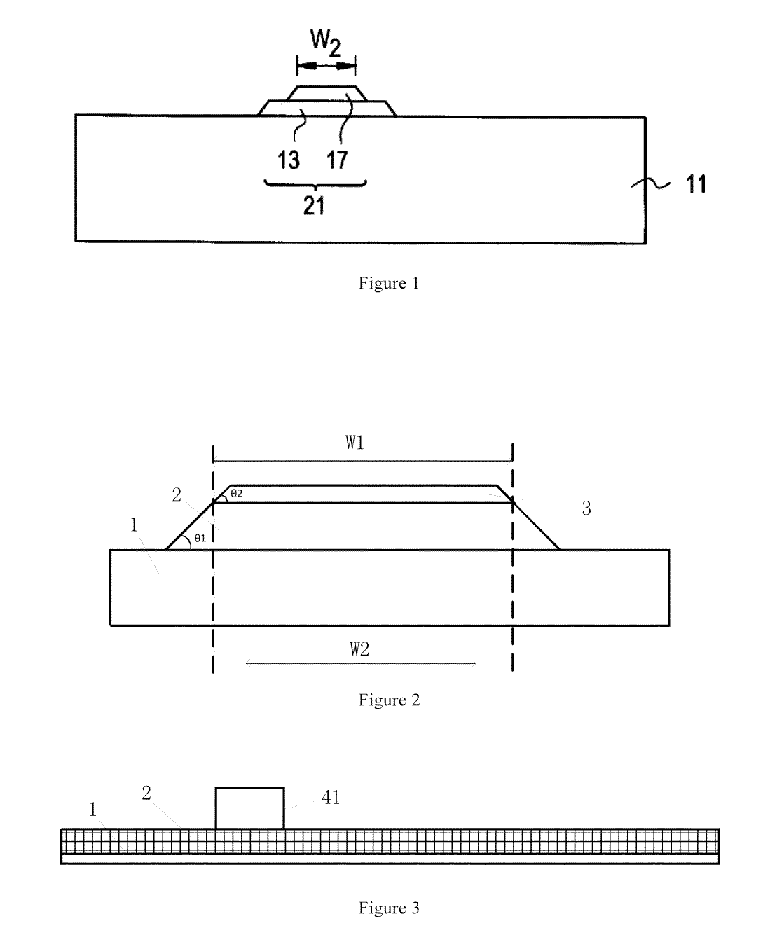

A TFT of an array substrate of an LCD device of one embodiment of the present invention comprises a gate electrode and a source electrode 9. As shown in FIG. 2, the gate electrode comprises a first metal layer block 2 and a second metal layer block 3 positioned on the first metal layer block 2, and the thermal expansion coefficient of the second metal layer block 3 is less than that of the first metal layer block 2. The top surface of the first metal layer block 2 is in contact with the bottom surface of the second metal layer block 3, and the width of the top surface of the first metal layer block 2 accords with that of the bottom surface of the second metal layer block 3. Namely, the width of the topline of the first metal layer block 2 is W1, and the width of the baseline of the second metal layer block is W2, W1=W2. The first metal layer block 2 can be made of metal such as Al, Cu, Au and the like which have a high expansion coefficient, and the second metal layer block 3 can be made of metal such as Mo, Ta, Co and the like which have a low expansion coefficient.

It is shown in FIG. 2 that the cross section of the first metal layer block 2 and the metal layer block 3 is a trapezoid. This is a specific structure of the gate electrode and can be formed by an etching process. Of course, other shapes such as rectangle, square and the like formed by other processes are also feasible as long as the width of the top surface of the first metal layer block 2 accords with that of the bottom surface of the second metal layer block 3.

Furthermore, the included angles formed by the bottoms and the side surfaces on the same side of the first metal layer block 2 and the second metal layer block 3 are the same, namely θ1=θ2. Preferably, 30°<θ1=θ2<60°, and more preferably, θ1=θ2=45°.

A manufacturing method of the aforementioned TFT comprises the following step A: Forming the first metal layer block on the substrate 1 and the second metal layer block positioned on the first metal layer block by exposure, development, and etching process, wherein the width of the top surface of the first metal layer block 2 accords with that of the bottom surface of the second metal layer block 3.

The invention will further be described in detail in accordance with the embodiments.

### Example 1

The step A comprises the following steps:

A1: Plating a first metal layer on the substrate 1, applying a first photoresist layer 41 on the first metal layer, and forming the first metal layer block 2 of the TFT gate electrode by exposure, development, and etching process; and

A2: Removing the first photoresist layer 41, plating a second metal layer on the first metal layer block 2, applying a second photoresist layer 42 in the position of the second metal layer corresponding to the first metal layer block 2, and forming the second metal layer block 3 of the TFT gate electrode by exposure, development, and etching process.

Furthermore, in the step A, the appointed degree of the included angle formed by the side and the bottom of the first metal layer block 2 and the second metal layer block 3 is achieved by controlling the etching time during etching process.

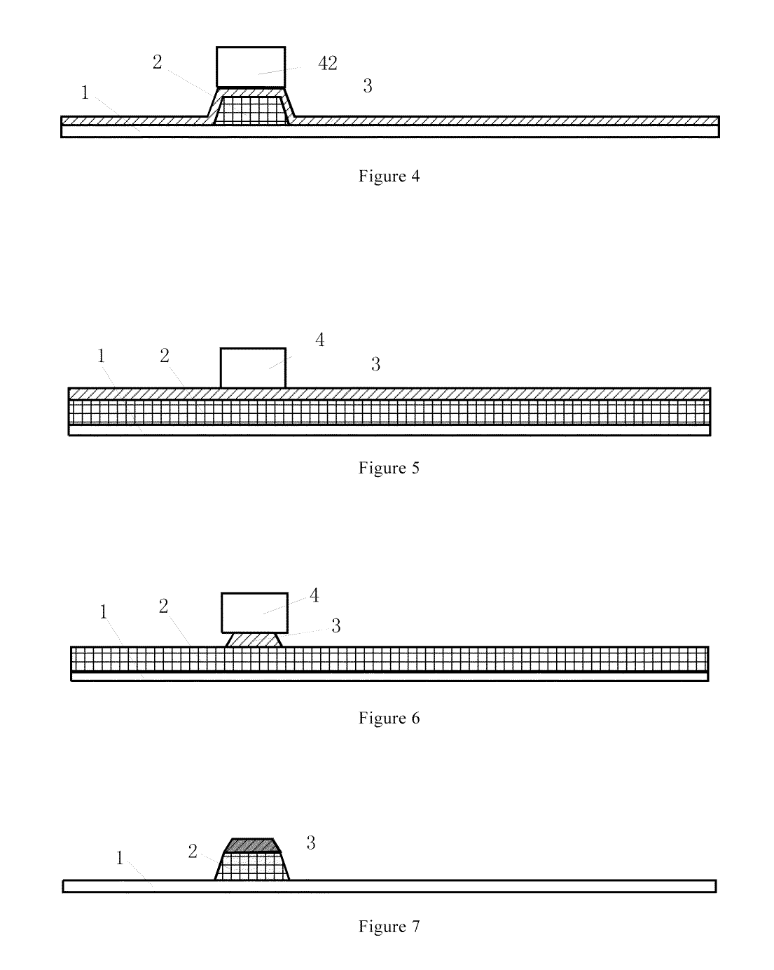

The specific steps of the overall manufacturing process are shown in FIG. 3, FIG. 4, and FIG. 7 to FIG. 10.

As shown in FIG. 3, the first metal layer is directly deposited on the substrate 1, and the first photoresist layer 41 is deposited on the first metal layer in accordance with the appointed width, shape, and position.

As shown in FIG. 4, the etching action is performed; the reserved first metal layer block 2 is kept; the photoresist layer on the first metal layer block 2 is removed; the second metal layer block 3 is deposited on the first metal layer block 2; and the reserved second photoresist layer 42 is kept on the second metal layer block 3 by the photolithography process.

As shown in FIG. 7, after the second photoresist layer 42 is formed, the second metal layer is etched; the reserved second metal layer block 3 is kept; the photoresist layer is removed; and thus the TFT gate electrode is completely manufactured.

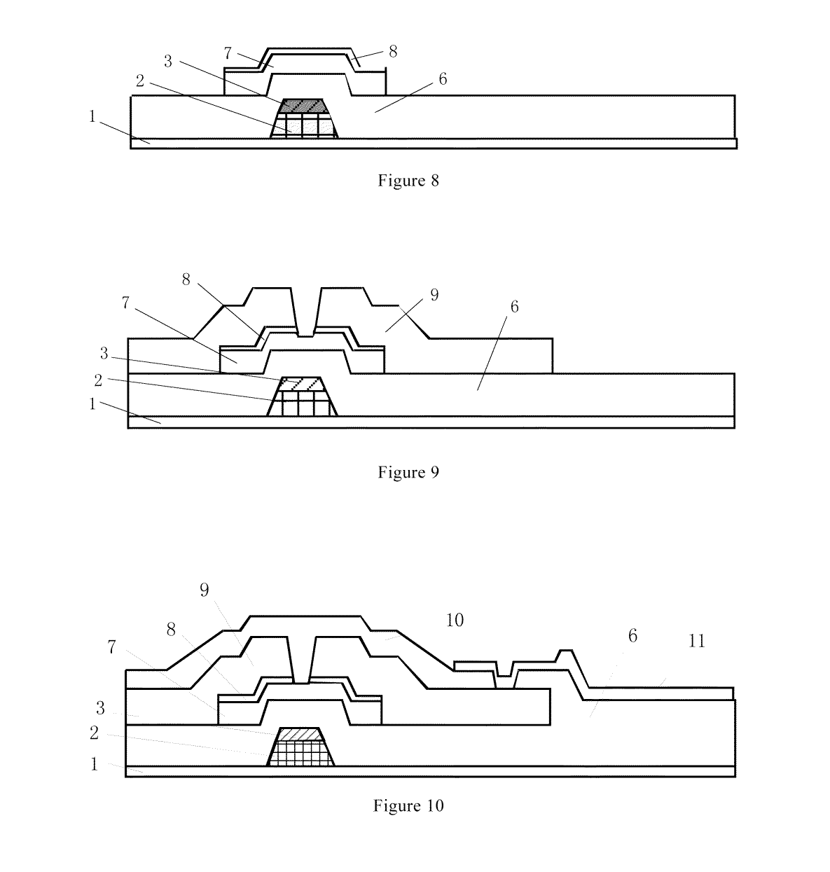

As shown in FIG. 8, after the first metal layer block and the second metal layer block 3 are formed, an insulating layer 6 is deposited on the second metal layer block 3 by chemical vapor deposition (CVD) by using the photolithography process, and a semiconductor layer 7 and an ohmic contact layer 8 are formed on an appointed place of the insulating layer 6.

As shown in FIG. 9, the third metal layer is deposited on the ohmic contact layer 8, and a TFT source electrode 9 is formed by using the photolithography process.

As shown in FIG. 10, after the source electrode 9 is formed, a second insulating layer 10 is formed on the source electrode 9 to protect the structure of the TFT. The third metal layer is exposed by the photolithography process and etching process (contact hole). The photic metal (such as ITO) is deposited to form a pixel electrode 11. Thus, a TFT with a gate electrode with double layer metal structure is formed by using the aforementioned method.

### Example 2

The step A comprises the following steps:

A1: Sequentially plating the first metal layer block 2 and the second metal layer on the substrate 1;

A2: Applying the photoresist layer 4, and forming the first metal layer block 2 of the TFT gate electrode by exposure, development, and etching process; and then etching the second metal layer by using the same photoresist layer 4 to form the second metal layer block 3.

Furthermore, in the step A, the appointed degree of the included angle formed by the side and bottom of the first metal layer block 2 and the second metal layer block 3 is achieved by controlling the etching time during etching process.

The specific steps of the overall manufacturing process are shown in FIG. 5, FIG. 6, and FIG. 7 to FIG. 10. Only the steps for manufacturing the gate electrode as shown in FIG. 5 and FIG. 6 are different from those of the example 1, and the subsequent steps are similar to those of the example 1.

As shown in FIG. 5, the first metal layer is directly deposited on the substrate 1; the second metal layer is directly deposited on the first metal layer; and the second photoresist layer 42 is deposited on the second metal layer in accordance with the appointed width, shape and position.

As shown in FIG. 6 and FIG. 7, after the photoresist layer 4 is formed, the second metal layer is etched. The first metal layer is etched after the reserved second metal layer block 3 is kept. The photoresist layer 4 is removed after the reserved first metal layer block 2 is kept (other parameters can be controlled by twice monometal etching or bimetal etching) , and thus the TFT gate electrode is completely manufactured.

As shown in FIG. 8, after the first metal layer block and the second metal layer block 3 are formed, the insulating layer 6 is deposited on the second metal layer block 3 by CVD by using the photolithography process, and the semiconductor layer 7 and the ohmic contact layer 8 are formed on the appointed place of the insulating layer 6.

As shown in FIG. 9, the third metal layer is deposited on the ohmic contact layer 8, and the TFT source electrode 9 is formed by using the photolithography process.

As shown in FIG. 10, after the source electrode 9 is formed, the insulating layer 10 is formed on the source electrode 9 to protect the structure of the TFT. The third metal layer is exposed by the photolithography process and etching process (contact hole). The photic metal (such as ITO) is deposited to form the pixel electrode 11. Thus, a TFT with a gate electrode with double layer metal structure is formed by using the aforementioned method.

The present invention is described in detail in accordance with the above contents with the specific preferred embodiments. However, this invention is not limited to the specific embodiments. For the ordinary technical personnel of the technical field of the present invention, on the premise of keeping the conception of the present invention, the technical personnel can also make simple deductions or replacements, and all of which should be considered to belong to the protection scope of the present invention.

We claim:

1. A thin film transistor (TFT) comprises a gate electrode and a source electrode, wherein said gate electrode comprises a first metal layer block and a second metal layer block positioned on the first metal layer block; the thermal expansion coefficient of said second metal layer block is less than that of said first metal layer block; the top surface of said first metal layer block is in contact with the bottom surface of said second metal layer block; and
the width of the top surface of said first metal layer block accords with that of the bottom surface of said second metal layer block.

2. The TFT of claim 1, wherein the cross section of said first metal layer block and said second metal layer block is a trapezoid.

3. The TFT of claim 2, wherein each included angle formed by the side surfaces with the bottoms of the first metal layer block and the second metal layer block is more than 30° and less than 60°.

4. The TFT of claim 3, wherein said included angle is 45°.

5. The TFT of claim 1, wherein the same included angles are formed by the bottoms with the side surfaces on the same side of said first metal layer block and said second metal layer block.

6. The TFT of claim 2, wherein the same included angles are formed by the bottoms with the side surfaces on the same side of said first metal layer block and said second metal layer block.

7. The TFT of claim 3, wherein the same included angles are formed by the bottoms with the side surfaces on the same side of said first metal layer block and said second metal layer block.

8. The TFT of claim 4, wherein the same included angles are formed by the bottoms with the side surfaces on the same side of said first metal layer block and said second metal layer block.

9. A manufacturing method of TFT comprises the following steps:
A: forming a first metal layer block and a second metal layer block positioned on the first metal layer block on a substrate by exposure, development, and etching process, wherein the width of the top surface of said first metal layer block accords with that of the bottom surface of said second metal layer block.

10. The manufacturing method of TFT of claim 9, wherein said step A comprises the following steps:
A1: plating a first metal layer on the substrate, applying a first photoresist layer on the first metal layer, and forming the first metal layer block of the TFT gate electrode by exposure, development, and etching;
A2: removing the first photoresist layer, plating a second metal layer on the first metal layer block, applying a second photoresist layer in the position of the second metal layer corresponding to the first metal layer block, and forming the second metal layer block of the TFT gate electrode by exposure, development, and etching process.

11. The manufacturing method of TFT of claim 9, wherein said step A comprises the following steps:
A1: sequentially plating a first metal layer and a second metal layer on the substrate;
A2: applying a photoresist layer, and forming the first metal layer block of the TFT gate electrode by exposure, development, and etching process; and then etching the second metal layer by using the same photoresist layer to form the second metal layer block.

12. The manufacturing method of TFT of claim 9, wherein in said step A, the appointed degree of the included angle formed by the side and bottom of the first metal layer block and the second metal layer block is achieved by controlling the etching time during etching process.

13. The manufacturing method of TFT of claim 10, wherein in said step A, the appointed degree of the included angle formed by the side and bottom of the first metal layer block and the second metal layer block is achieved by controlling the etching time during etching process.

14. The manufacturing method of TFT of claim 11, wherein in said step A, the appointed degree of the included angle formed by the side and bottom of the first metal layer block and the second metal layer block is achieved by controlling the etching time during etching process.

15. The array substrate comprises a TFT of claim 1, wherein said TFT comprises a gate electrode and a source electrode; said gate electrode comprises a first metal layer block and a second metal layer block positioned on the first metal layer block; the thermal expansion coefficient of said second metal layer block is less than that of said first metal layer block; the top surface of said first metal layer block is in contact with the bottom surface of said second metal layer block, and the width of the top surface of said first metal layer block accords with that of the bottom surface of said second metal layer block.

16. The array substrate of claim 15, wherein the cross section of said first metal layer block and said second metal layer block is a trapezoid.

17. The array substrate of claim 16, wherein each included angle formed by the side surfaces and the bottoms of the first metal layer block and the second metal layer block is more than 30° and less than 60°.

18. The array substrate of claim 17, wherein said included angle is 45°.

19. A liquid crystal display (LCD) device comprises an array substrate of claim 15, wherein said array substrate comprises the TFT of claim 1; said TFT comprises a gate electrode and a source electrode; said gate electrode comprises a first metal layer block and a second metal layer block positioned on the first metal layer block; the thermal expansion coefficient of said second metal layer block is less than that of said first metal layer block; the top surface of said first metal layer block is in contact with the bottom surface of said second metal layer block; and the width of the top surface of said first metal layer block accords with that of the bottom surface of said second metal layer block.

20. The LCD device of claim 19, wherein the cross section of said first metal layer block and said second metal layer block is a trapezoid.

21. The LCD device of claim 20, wherein each included angle formed by the side surfaces and the bottoms of the first metal layer block and the second metal layer block is more than 30° and less than 60°.

22. The LCD device of claim 21, wherein said included angle is 45°.
